(19) United States
(12) Patent Application Publication
(10) Pub. No.: US 2012/0199183 A1
(43) Pub. Date: Aug. 9, 2012

(54) SOLAR CELL AND METHOD OF MANUFACTURING THE SAME

(76) Inventors: Min Seok OH, Yongin-si (KR); Nam-Kyu Song, Yongin-si (KR); Min Park, Yongin-si (KR); Yeon-Ik Jang, Yongin-si (KR); Hoon Ha Jeon, Yongin-si (KR); Yun-Seok Lee, Yongin-si (KR); Cho-Young Lee, Yongin-si (KR)

(21) Appl. No.: 13/271,749

(22) Filed: Oct. 12, 2011

(30) Foreign Application Priority Data
Feb. 8, 2011 (KR) 2011-0010891

(51) Int. Cl. H01L 31/02; H01L 31/18

(52) U.S. Cl. 136/252; 438/98; 257/E31.124

(57) ABSTRACT

The solar cell includes a substrate, a semiconductor layer, a first doped pattern and a second doped pattern. The substrate has a first surface adapted to receive solar light and a second surface opposite to the first surface. The semiconductor layer includes an insulating pattern formed on a first area of the second surface of the substrate and a semiconductor pattern formed on a second area of the second surface of the substrate in which the insulating pattern is not formed. The first doped pattern and the second doped pattern are formed either in or on the semiconductor pattern.

### CROSS-REFERENCE TO RELATED APPLICATION

This application claims priority under 35 U.S.C. §119 to Korean Patent Application No. 2011-0010891, filed on Feb. 8, 2011, the disclosure of which is hereby incorporated by reference in its entirety.

### BACKGROUND OF THE INVENTION

1. Technical Field

Example embodiments of the present invention relate to a solar cell and a method of manufacturing the solar cell. More particularly, example embodiments of the present invention relate to a solar cell having a backside contact type and a method of manufacturing the solar cell.

2. Description of the Related Art

Generally, a solar cell has a front surface receiving solar light and a rear surface opposite to the front surface, and is an energy conversion element converting a solar light energy into an electrical energy using a photovoltaic effect of the solar cell due to the solar light. When the solar light is incident into the solar cell, electrons and holes may be generated inside of a substrate of the solar cell, and the photovoltaic effect which is a potential difference between a first electrode and a second electrode of the solar cell is generated as the electrons and holes respectively move to the first electrode and the second electrode. Then, when the solar cell is loaded, a current may flow through the solar cell.

The solar cell may include, for example, the first electrode formed on the front surface and the second electrode formed on the rear surface. Since the first electrode is formed on the front surface receiving the solar light, the absorption rate of the solar light may be decreased by an area in which the first electrode is formed.

In addition, when the solar cell includes the first electrode formed on the front surface, the solar cell may further include, for example, p-type amorphous silicon or n-type amorphous silicon collecting the electrons or the holes and a transparent conductive oxides (TCO) making an ohmic contact between the amorphous silicon and the first electrode. Since the amorphous silicon and the TCO may absorb the solar light, the absorption rate of the solar light incident into the front surface may be decreased. Consequently, there is a need in the art for a solar cell capable of increasing the absorption rate of the solar light incident into the solar cell and for a method of manufacturing the same.

### SUMMARY OF THE INVENTION

Example embodiments of the present invention provide a solar cell capable of increasing the absorption rate of the solar light incident into the solar cell.

Example embodiments of the present invention also provide a method of manufacturing various kinds of solar cells including the above-mentioned solar cell.

According to an example embodiment of the present invention, the solar cell includes a substrate, a semiconductor layer, a first doped pattern and a second doped pattern. The substrate has a first surface adapted to receive solar light and a second surface opposite to the first surface. The semiconductor layer includes an insulating pattern formed on a first area of the second surface of the substrate and a semiconductor pattern formed on a second area of the second surface of the substrate in which the insulating pattern is not formed. The first doped pattern and the second doped pattern are formed either in or on the semiconductor pattern.

In the example embodiment, the semiconductor layer may have a thickness between about 100 Å and about 200 Å. The semiconductor pattern may include a first semiconductor pattern and a second semiconductor pattern spaced apart from the first semiconductor pattern. The first doped pattern may be formed in the first semiconductor pattern, and the second doped pattern may be formed in the second semiconductor pattern.

In the example embodiment, the semiconductor layer may have a thickness between about 50 Å and about 100 Å. The semiconductor pattern may include a first semiconductor pattern and a second semiconductor pattern spaced apart from the first semiconductor pattern. The first doped pattern may be formed on the first semiconductor pattern, and the second doped pattern may be formed on the second semiconductor pattern.

According to an example embodiment of the present invention, the method of manufacturing the solar cell is provided. In the method, a semiconductor layer is formed on a second surface of a substrate opposite to a first surface of the substrate. The first surface is adapted to receive solar light. The first impurity gas adheres on the semiconductor layer. A laser is injected onto the semiconductor layer to form a first doped pattern in the semiconductor layer.

In an example embodiment, in the method, a contact layer may be further formed on the first doped pattern using one of a reactive plasma deposition (RPD) method, an ion plating deposition method and an inkjet printing method.

In an example embodiment, in the method, an electrode electrically connected to the first doped pattern may be further formed on the contact layer.

In an example embodiment, in the method, a second impurity gas may further adhere on the semiconductor layer having the first doped pattern. A laser may be further injected onto the semiconductor layer to form a second doped pattern in the semiconductor layer and spaced apart from the first doped pattern.

In an example embodiment, the semiconductor layer may have a thickness between about 100 Å and about 200 Å. The first and the second doped patterns may be formed in the semiconductor layer.

In an example embodiment, the first impurity gas may include one of boron trichloride (BCl₃) and diborane (B₂H₆), and the second impurity gas may include phosphine (PH₃).

In an example embodiment, the semiconductor layer may include an insulation pattern and a semiconductor pattern. When the semiconductor layer is formed, the insulation pattern may be formed by an inkjet printing method on a first area of the second surface of the substrate, and the semiconductor pattern may be formed on a second area of the second surface of the substrate in which the insulation pattern is not formed.

According to an example embodiment of the present invention, the method of manufacturing the solar cell is provided. In the method, a semiconductor layer is formed on a second surface of a substrate opposite to a first surface of the substrate. The first surface is adapted to receive solar light. A first mask having an opening portion is formed over the semiconductor layer. A first plasma is provided to the semiconductor layer through the first mask to form a first doped pattern in or on the semiconductor layer.

In the example embodiment, in the method, a contact layer may be formed on the first doped pattern using one of a reactive plasma deposition (RPD) method, an ion plating deposition method and an inkjet printing method.

In an example embodiment, in the method, an electrode electrically connected to the first doped pattern may be formed on the contact layer.

In an example embodiment, in the method, a second mask having an opening portion may be disposed over the semiconductor layer having the first doped pattern. A second plasma may be provided to the semiconductor layer through the second mask to form a second doped pattern in or on the semiconductor layer and spaced apart from the first doped pattern.

In the example embodiment, the semiconductor layer may have a thickness between about 100 Å and about 200 Å. The first and the second doped patterns may be formed in the semiconductor layer.

In an example embodiment, the first plasma may be generated from boron trichloride (BCl₃) and diborane (B₂H₆), and the second plasma may be generated from phosphine (PH₃).

In an example embodiment, the semiconductor layer may have a thickness between about 50 Å and about 100 Å. The first and the second doped patterns may be deposited on the semiconductor layer.

In an example embodiment, the first plasma may be generated from boron trichloride (BCl₃) and diborane (B₂H₆), silane (SiH₄) and hydrogen (H₂), and the second plasma may be generated from phosphine (PH₃), silane (SiH₄) and hydrogen (H₂).

In an example embodiment, the semiconductor layer may include an insulation pattern and a semiconductor pattern. When the semiconductor layer is formed, the insulation pattern is formed by an inkjet printing method on a first area of the second surface of the substrate, and the semiconductor pattern is formed on a second area of the second surface of the substrate in which the insulating pattern is not formed.

In the example embodiment, the semiconductor layer may have a thickness between about 100 Å and about 200 Å. The first doped pattern may be formed in the semiconductor pattern.

In an example embodiment, the semiconductor layer may have a thickness between about 50 Å and about 100 Å. The first doped pattern may have deposited on the semiconductor pattern.

According to example embodiments of the present invention, first and second doped patterns are formed on a rear surface of a substrate of a solar cell, so that a loss of solar light incident into a front surface of the substrate of the solar cell may be decreased.

In addition, the first and second doped patterns are formed in or on a semiconductor layer including an i-type amorphous semiconductor, so that the first doped pattern may be electrically insulated from the second doped pattern.

In addition, a first passivation film includes the i-type amorphous semiconductor, so that an absorption rate of the solar light may be increased.

In accordance with an example embodiment of the present invention, a solar cell is provided. The solar cell includes a substrate having an uneven first surface adapted to receive solar light and a second surface opposite to the first surface, a semiconductor layer formed on the second surface of the substrate and a first doped pattern and a second doped pattern formed in or on the semiconductor layer.

### BRIEF DESCRIPTION OF THE DRAWINGS

Exemplary embodiments of the present invention can be understood in more detail from the following detailed description taken in conjunction with the accompanying drawings, in which:

FIG. 1 is a perspective view illustrating a solar cell according to an example embodiment of the present invention;

FIG. 2 is a cross-sectional view taken along a line I-I′ of FIG. 1;

FIGS. 3A to 3G are cross-sectional views illustrating processes of manufacturing the solar cell of FIG. 1;

FIGS. 4A and 4B are cross-sectional views illustrating processes of manufacturing a solar cell according to an example embodiment of the present invention;

FIG. 5 is a perspective view illustrating a solar cell according to an example embodiment of the present invention;

FIG. 6 is a cross-sectional view taken along a line II-II′ of FIG. 5;

FIGS. 7A to 7D are cross-sectional views illustrating processes of manufacturing the solar cell of FIG. 5;

FIG. 8 is a perspective view illustrating a solar cell according to an example embodiment of the present invention;

FIG. 9 is a cross-sectional view taken along a line III-III′ of FIG. 8; and

FIGS. 10A to 10F are cross-sectional views illustrating processes of manufacturing the solar cell of FIG. 8.

### DETAILED DESCRIPTION OF EXAMPLE EMBODIMENTS OF THE INVENTION

Hereinafter, example embodiments of the present invention will be explained in detail with reference to the accompanying drawings.

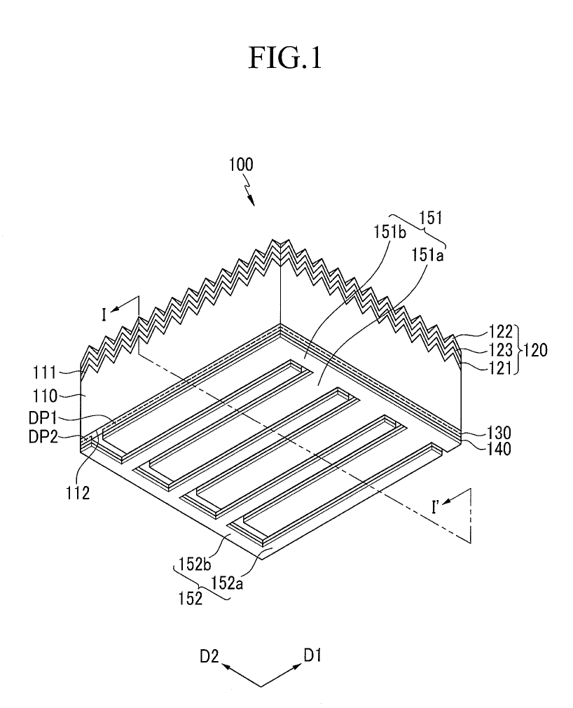

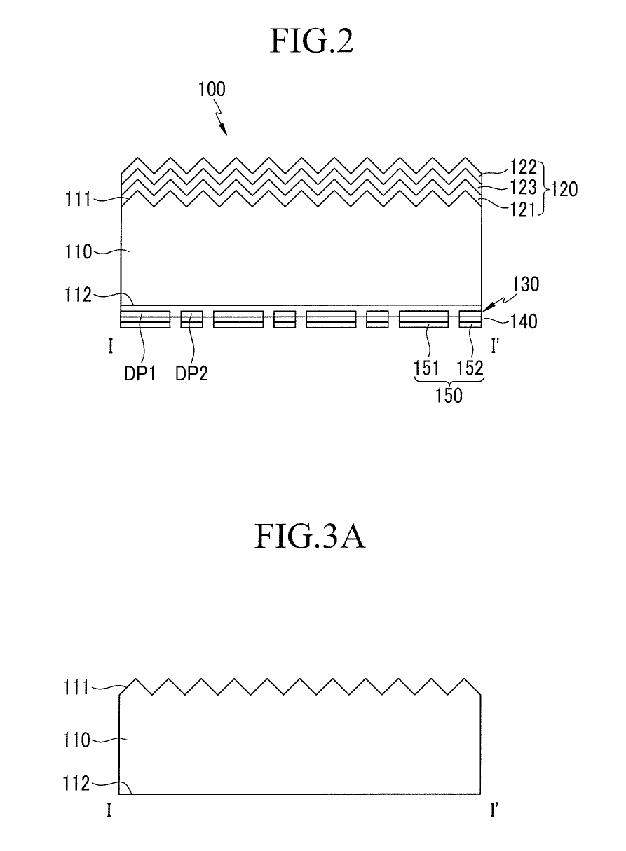

FIG. 1 is a perspective view illustrating a solar cell according to an example embodiment of the present invention. FIG. 2 is a cross-sectional view taken along a line I-I′ of FIG. 1.

Referring to FIGS. 1 and 2, a solar cell 100 includes, for example, a substrate 110, a protection layer 120, a semiconductor layer 130, a contact layer 140 and an electrode layer 150.

The substrate 110 has a front surface 111 receiving the solar light and a rear surface 112 opposite to the front surface 111. The substrate 110 may be, for example, an n-type (negative type) crystalline silicon substrate or a p-type (positive type) crystalline silicon substrate. For example, the substrate 110 according to the present example embodiment of FIG. 1 is the n-type crystalline silicon substrate. The substrate 110 receives the solar light to generate holes and electrons by photons of the solar light in the substrate 110. The holes drift toward the substrate 110 which is the n-type crystalline silicon substrate and a first doped pattern DP1 which includes, for example, p-type amorphous silicon, and the electrons drift toward a second doped pattern DP2 which includes, for example, n-type amorphous silicon. The holes drifting toward the first doped pattern DP1 and the electrons drifting toward the second doped pattern DP2 are accumulated in the electrode layer 150. The front surface 111 of the substrate 110 is uneven to increase an absorption rate of the solar light.

The protection layer 120 includes, for example, a first passivation film 121 and an anti-reflection film 122. The protection layer 120 may further include, for example, a second passivation film 123.

The first passivation film 121 is formed on the uneven front surface 111 of the substrate 110. The first passivation film 121 may prevent the holes and the electrons generated in the substrate 110 from being rejoined. The first passivation film 121 may include one of, for example, i-type (intrinsic type) amorphous silicon, silicon oxide (SiOₓ) and aluminium oxide (Al₂O₃). For example, when the first passivation film 121 includes i-type amorphous silicon, since a film characteristic of i type amorphous silicon may be more beneficial than that of p type or n type amorphous silicon, the first passivation film 121 may decrease a loss of the holes and electrons generated in the substrate 110. The first passivation film 121 may have a thickness between, for example, about 50 Å and about 200 Å.

The anti-reflection film 122 is formed on the first passivation film 121. The anti-reflection film 122 prevents the solar light from being reflected, when the front surface 111 of the substrate 110 receives the solar light. The anti-reflection film 122 may include, for example, silicon nitride (SiNx). The anti-reflection film 122 may have a thickness between, for example, about 700 Å and about 1000 Å.

The second passivation film 123 is formed on the first passivation film 121. The second passivation film 123 may be disposed between the first passivation film 121 and the anti-reflection film 122. The second passivation film 123 may include, for example, n-type amorphous silicon. Alternatively, the second passivation film 123 may be omitted.

The semiconductor layer 130 is formed on the rear surface 112 of the substrate 110. The semiconductor layer 130 may include, for example, i-type amorphous silicon. The semiconductor layer 130 may have a thickness between, for example, about 100 Å and about 200 Å. The semiconductor layer 130 includes the first doped pattern DP1 and the second doped pattern DP2. The first doped pattern DP1 includes, for example, p-type silicon doped with a first impurity gas. The first impurity gas may be, for example, boron trichloride (BCl₃) or diborane (B₂H₆). The second doped pattern DP2 includes, for example, n-type silicon (or (n+)-type silicon) doped with a second impurity gas. The second impurity gas may be, for example, phosphine (PH₃).

The first doped pattern DP1 and the second doped pattern DP2 are spaced apart from each other. For example, the first doped pattern DP1 according to the present example embodiment includes first patterns extended in the first direction D1 and arranged in parallel in the second direction D2 crossing the first direction D1, and a second pattern extended in the second direction D2 and connecting the first patterns with each other. The second doped pattern DP2 includes third patterns extended in the first direction D1 and arranged in parallel in the second direction D2, and a fourth pattern extended in the second direction D2 and connecting the third patterns with each other. The first patterns and the third patterns are alternately disposed, and the second pattern and the fourth pattern are opposite to each other. It is noted that example embodiments of the present invention are not limited to the above-mentioned specific directions and positions for the first and second patterns of the first doped pattern DP1 and the third and fourth patterns of the second doped pattern DP2 but rather the positions and directions for the first, second, third and fourth patterns may be varied in accordance with example embodiments of the present invention as is understood by one skilled in the art.

The contact layer 140 is formed on the first and the second doped patterns DP1 and DP2 of the semiconductor layer 130. The contact layer 140 is formed between the semiconductor layer 130 and the electrode layer 150 to form the ohmic contact. The contact layer 140 may include, for example, transparent conductive oxides (TCO) having at least one of tin (Sn), tungsten (W), titanium (Ti), molybdenum (Mo), zinc (Zn) and tantalum (Ta) added to indium oxide, tin oxide, or zirconium oxide. The contact layer 140 may have the thickness between, for example, about 100 Å and about 700 Å. Since the contact layer 140 is formed on the first and second doped patterns DP1 and DP2, the contact layer 140 may have substantially the same shape as the first and second doped patterns DP1 and DP2.

The electrode layer 150 is formed on the contact layer 140. The electrode layer 150 may have substantially the same shape as the first and the second doped patterns DP1 and DP2, such as the contact layer 140. The electrode layer 150 includes a first electrode 151 formed along the first doped pattern DP1 and a second electrode 152 formed along the second doped pattern DP2. Each of the first and the second electrodes 151 and 152 may include, for example, a seed layer, a main electrode and a capping layer. The main electrode is formed on the seed layer, and the capping layer is formed on the main electrode. For example, seed layer may include silver (Ag) or nickel (Ni), the main electrode may include silver (Ag) or copper (Cu), and the capping layer may include tin (Sn). It is noted that example embodiments of the present invention are not limited to the above-mentioned number of electrode layers and that the number of electrode layers may be varied in accordance with example embodiments of the present invention as is understood by one skilled in the art.

The first electrode 151 may include, for example, first finger electrodes 151a formed along the first patterns and a first bus electrode 151b formed along the second pattern, and the second electrode 152 may include second finger electrodes 152a formed along the third patterns and a second bus electrode 152b formed along the fourth pattern. Thus, the first finger electrodes 151a and the second finger electrodes 152a are alternately disposed, and the first bus electrode 151b and the second bus electrode 152b are opposite to each other.

Alternatively, for example, the respective positions of the uneven front surface 111 of the substrate 110 and the rear surface 112 of the substrate 110 as depicted in FIGS. 1 and 2 may be switched such that the rear surface 112 of the substrate 110 and the elements formed thereon (e.g., the semiconductor layer 130, first and second doped patterns, DP1 and DP2, the contact layer 140 and the electrode layer 150) may now instead be located at the upper portion of the solar cell and the uneven front surface 111 of the substrate 110 and the elements formed thereon (e.g. protection film 120) may now instead be located on a bottom portion of the solar cell as is understood by one skilled in the art.

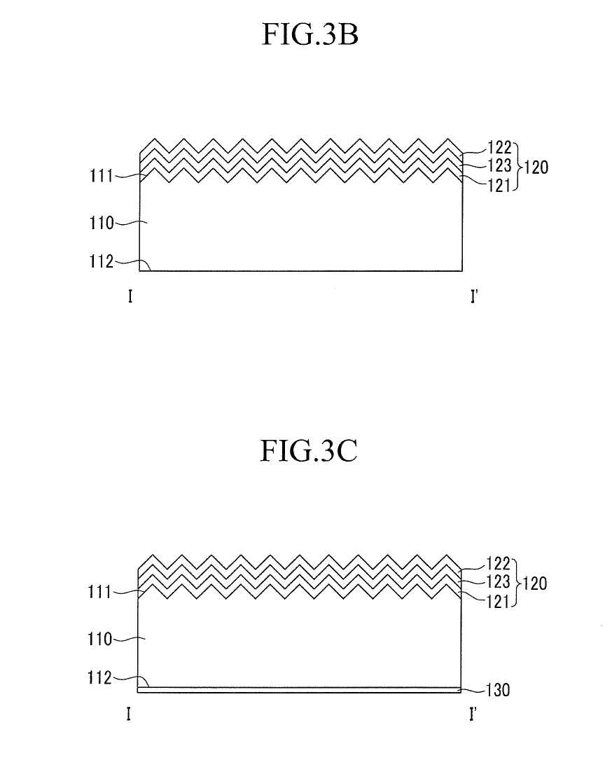

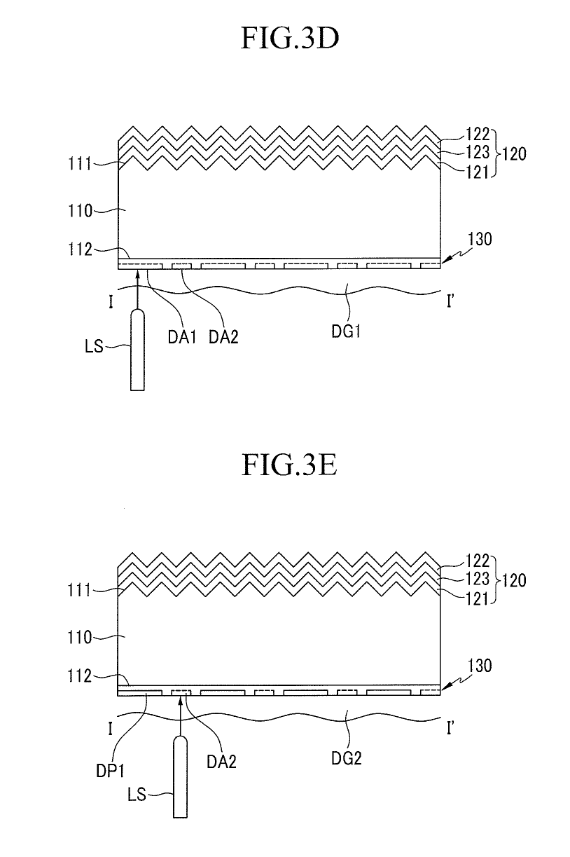

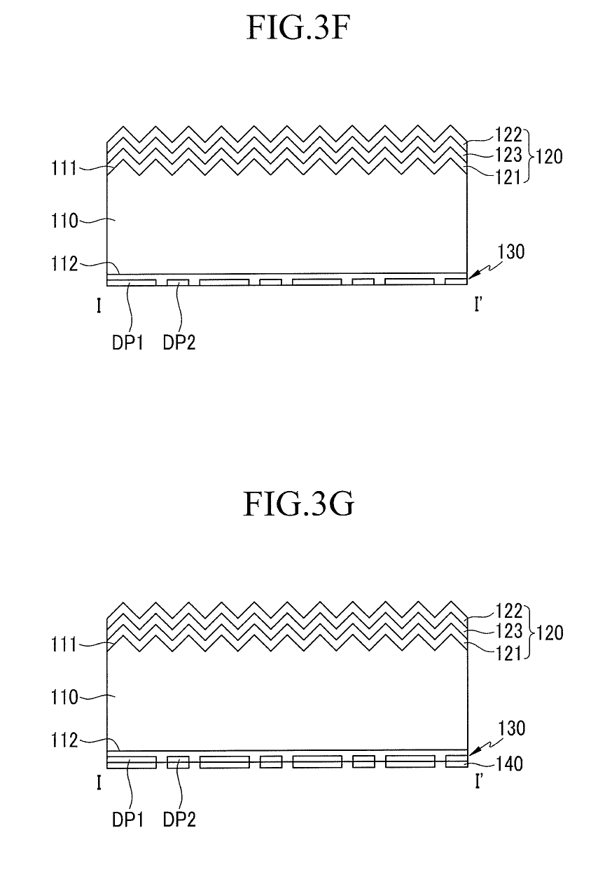

FIGS. 3A to 3G are cross-sectional views illustrating processes of manufacturing the solar cell of FIG. 1.

Referring to FIG. 3A, the front surface 111 of the substrate 110 is textured to have an uneven surface. For example, the front surface 111 of the substrate 110 may be wet-etched or dry-etched to have an uneven surface.

In the wet-etching method, the substrate 110 is etched using an etching solution, so that an uneven front surface 111 and an uneven rear surface 112 of the substrate 110 are formed. For example, the etching solution includes isopropyl alcohol (IPA) or surfactant added to alkali solution such as potassium hydroxide (KOH) or sodium hydroxide (NaOH). The protection layer 120 is formed on the uneven front surface 111. The protection layer 120 includes, for example, silicon oxide (SiOₓ). Then, the uneven rear surface 112 is processed by the alkali solution to become an even rear surface 112. Then, the front surface 111 on which the protection layer 120 is formed is rinsed, and the protection layer 120 is removed. Thus, the front surface 111 of the substrate 110 only remains uneven.

Alternatively, in the dry-etching method, the substrate 110 is etched using, for example, a reactive ion, so that the uneven front surface 111 of the substrate 110 is formed. At least one of, for example, chlorine (Cl₂), tetrafluoromethane (CF₄), sulfur hexafluoride (SF₆), fluoroform (CHF₃) and oxygen (O₂) may be used in the reactive ion etching.

Referring to FIG. 3B, the protection layer 120 is formed on the uneven front surface 111. For example, the first passivation film 121 and the anti-reflection film 122 are sequentially formed on the uneven front surface 111. The first passivation film 121 and the anti-reflection film 122 may be formed using a deposition method such as, for example, a chemical vapor deposition (CVD) method, a sputtering method, etc. The first passivation film 121 may include, for example, one of i-type amorphous silicon, silicon oxide (SiOₓ) and aluminium oxide (Al₂O₃). For example, the first passivation film 121 may have a thickness between about 50 Å and about 200 Å, and the anti-reflection film 122 may have a thickness between about 700 Å and about 1000 Å.

Alternatively, the second passivation film 123 may be further formed, for example, between the first passivation film 121 and the anti-reflection film 122. The second passivation film 123 may be formed, for example, using the deposition method such as the CVD method, the sputtering method, etc. The second passivation film 123 may include, for example, n-type amorphous silicon. Alternatively, the second passivation film may be omitted.

Referring to FIG. 3C, the semiconductor layer 130 is formed on the rear surface 112 of the substrate 110 after the protection layer 120 has been formed on the uneven front surface 111 of the substrate 110. The semiconductor layer 130 may be formed using, for example, a plasma enhanced chemical vapor deposition (PECVD) method.

For example, the semiconductor layer 130 is deposited using plasma of i-type amorphous silicon, plasma of silane (SiH₄) and plasma of hydrogen (H₂). The semiconductor layer 130 may have, for example, a thickness between about 100 Å and about 200 Å considering the thicknesses of the first doped pattern and the second doped pattern.

Referring to FIG. 3D, the first impurity gas (DG1) is doped into a first doping area DA1 of the semiconductor layer 130 using, for example a gas immersion laser doping (GILD) method. For example, the substrate 110 on which the semiconductor layer 130 is formed is disposed in a chamber emitting the first impurity gas DG1, and the first impurity gas DG1 adheres on a surface of the semiconductor layer 130. The first impurity gas DG1 may be, for example, boron trichloride (BCl₃) or diborane (B₂H₆).

Then, a laser LS, as an energy source, is injected onto the surface of the semiconductor layer 130 on which the first impurity gas DG1 adheres and the first impurity gas DG1 is selectively doped into the first doping area DA1 of the semiconductor layer 130. The first doping area DA1 may have a depth, for example, between about 50 Å and about 100 Å. After the first impurity gas DG1 is doped, the first impurity gas DG1 remaining on the surface of the semiconductor layer 130 may be removed, for example, using a dry rinsing.

Referring to FIG. 3E, the second impurity gas (DG2) is doped into a second doping area DA2 using the GILD method, and the second doping area DA2 is spaced apart from the first doping area DA1 of the semiconductor layer 130 having the first doped pattern DP1 formed in the first doping area DA1 according to the above-mentioned process referring to FIG. 3D. For example, the substrate 110 having the first doped pattern DP1 is disposed in the chamber emitting the second impurity gas DG2, and the second impurity gas DG2 adheres on the surface of the semiconductor layer 130. The second impurity gas DG2 may be, for example, phosphine (PH₃).

Then, the laser LS, as the energy source, is injected onto the surface of the semiconductor layer 130 on which the second impurity gas DG2 adheres, and the second impurity gas DG2 is selectively doped into the second doping area DA2 spaced apart from the first doping area DA1 of the semiconductor layer 130. The second doping area DA2 may have the depth, for example, between about 50 Å and about 100 Å.

Referring to FIG. 3F, the second doped pattern DP2 is formed in the second doping area DA2 according to the above-mentioned process referring to FIG. 3E. The second doped pattern DP2 may, for example, have a width smaller than that of the first doped pattern DP1. The second doped pattern DP2 is spaced apart from the first doped pattern DP1 by a predetermined distance, so that the first and second doped patterns DP1 and DP2 may be insulated from each other by the semiconductor layer 130 in which the first and second doped patterns DP1 and DP2 are formed. After the second impurity gas DG2 is doped, the second impurity gas DG2 remaining on the surface of the semiconductor layer 130 may be removed by, for example, the dry rinsing.

Referring to FIG. 3G, the contact layer 140 is formed on the first and second doped patterns DP1 and DP2 of the semiconductor layer 130 using, for example, a reactive plasma deposition (RPD) method, an ion plating deposition method or an inkjet printing method. For example, in the RPD method or the ion plating deposition method, the TCO having at least one of tin (Sn), tungsten (W), titanium (Ti), molybdenum (Mo), zinc (Zn) and tantalum (Ta) added to indium oxide, tin oxide, or zirconium oxide is deposited on the first and second doped patterns DP1 and DP2 using a shadow mask having an opening portion corresponding to the first and second doped patterns DP1 and DP2, so that the contact layer 140 may be formed on the first and second doped patterns DP1 and DP2.

Alternatively, for example, in the inkjet printing method, the TCO may be deposited on the first and second doped patterns DP1 and DP2, so that the contact layer 140 may be formed on the first and second doped patterns DP1 and DP2. The contact layer 140 may have a thickness, for example, between about 100 Å and about 700 Å.

Referring to FIG. 2 again, the electrode layer 150 is formed on the contact layer 140 using, for example, a screen printing method. In the screen printing method, a mask having an opening portion corresponding to the contact layer 140 is disposed on the substrate 110 having the contact layer 140, and silver (Ag) or copper (Cu) is spread on the substrate 110 on which the mask is disposed, so that the electrode layer 150 having a single layer is formed.

Alternatively, for example, although not shown, the seed layer having Ag or nickel (Ni) is formed on the contact layer 140 using the inkjet printing method, the main electrode having Ag or Cu is formed on the seed layer using the screen printing method, and the capping layer having Sn is formed on the main electrode using a plating method, so that the electrode layer having three layers may be formed.

The electrode layer 150 includes a first electrode 151 corresponding to the first doped pattern DP1 and a second electrode 152 corresponding to the second doped pattern DP2. It is noted that example embodiments of the present invention are not limited to the above-mentioned number of electrode layers and that the number of electrode layers may be varied in accordance with example embodiments of the present invention as is understood by one skilled in the art. As depicted in the example embodiment of FIG. 1, the first and second doped patterns DP1 and DP2 are formed in the semiconductor layer 130 which is formed on the rear surface 112 of the substrate 110 using the first impurity gas (DG1) and the laser LS, so that a loss of the solar light incident into the front surface 111 of the substrate 110 may be decreased.

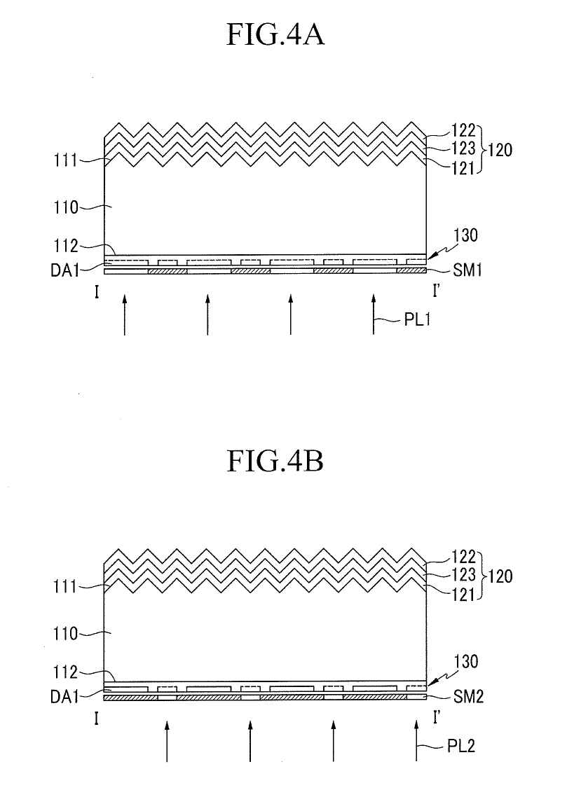

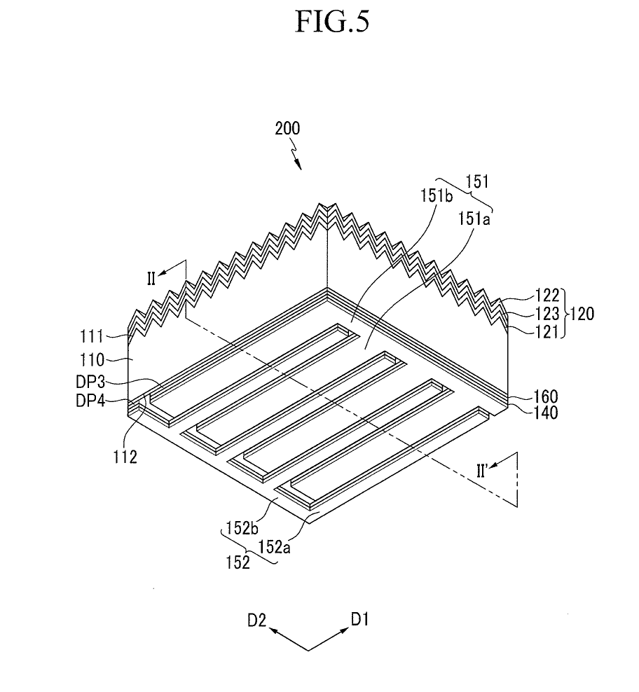

FIGS. 4A and 4B are cross-sectional views illustrating processes of manufacturing a solar cell according to another example embodiment of the present invention.

The solar cell according to the present example embodiment of FIGS. 4A and 4B is substantially the same as the solar cell according to the previous example embodiment of FIG. 1 except for a method of forming first and second doped patterns. Thus, the same reference numerals will be used to refer to the same or like parts as those described in the previous example embodiment of FIG. 1 and any repetitive explanation concerning the above elements will be omitted.

For example, referring to FIG. 4A, a first impurity gas is doped into a first doping area DA1 of a semiconductor layer 130 including i-type amorphous silicon using a plasma doping (PLAD) method. For example, a first shadow mask SM1 having an opening portion corresponding to the first doping area DA1 is disposed over the substrate 110 having the semiconductor layer 130. The substrate 110 is disposed in a chamber emitting a first impurity gas. In the chamber, a high energy due to a discharge of electricity and so on, is applied to the first impurity gas to generate a first plasma (PL1) from the first impurity gas, and the first plasma (PL1) including ions in Group III is selectively doped into the first doping area DA1 of the semiconductor layer 130. For example, the first impurity gas may be boron trichloride (BCl₃) or diborane (B₂H₆), and the ions in Group III may be boron (B) ion. The first doped pattern DP1 may have, for example, a thickness between about 50 Å and about 100 Å. Then, the first doped pattern DP1 may be activated by, for example, a heat treatment or a laser machining.

Referring FIG. 2 and FIG. 4B, a second impurity gas is doped into a second doping area DA2 of the semiconductor layer 130 having the first doped pattern DP1 formed in the first doping area DA1 according to the above-mentioned process referring to FIG. 4A using the PLAD method. For example, a second shadow mask SM2 having an opening portion corresponding to the second doping area DA2 is disposed over the substrate 110 having the first doping patter DP1. The substrate 110 is disposed in the chamber emitting a second impurity gas. In the chamber, the high energy due to the discharge of electricity and so on is applied to the second impurity gas to generate second plasma PL2, and the second plasma PL2 including ions in Group V is selectively doped into the second doping area DA2 of the semiconductor layer 130. The second impurity gas DG2 may be, for example, phosphine (PH₃), and the ions in Group V may be phosphorus (P) ion. Accordingly, the second doped pattern DP2 is formed in the second doping area DA2. The second doping patter DP2 may have, for example, a thickness between about 50 Å and about 100 Å. Then, the second doped pattern DP2 may be activated by, for example, the heat treatment or the laser machining.

According to the present example embodiment of FIG. 4A and FIG. 4B, the first and second patterns DP1 and DP2 are formed in the semiconductor layer 130 which is formed on the rear surface 112 of the substrate 110 using the plasma, so that a loss of the solar light incident into the front surface 111 of the substrate 110 may be decreased.

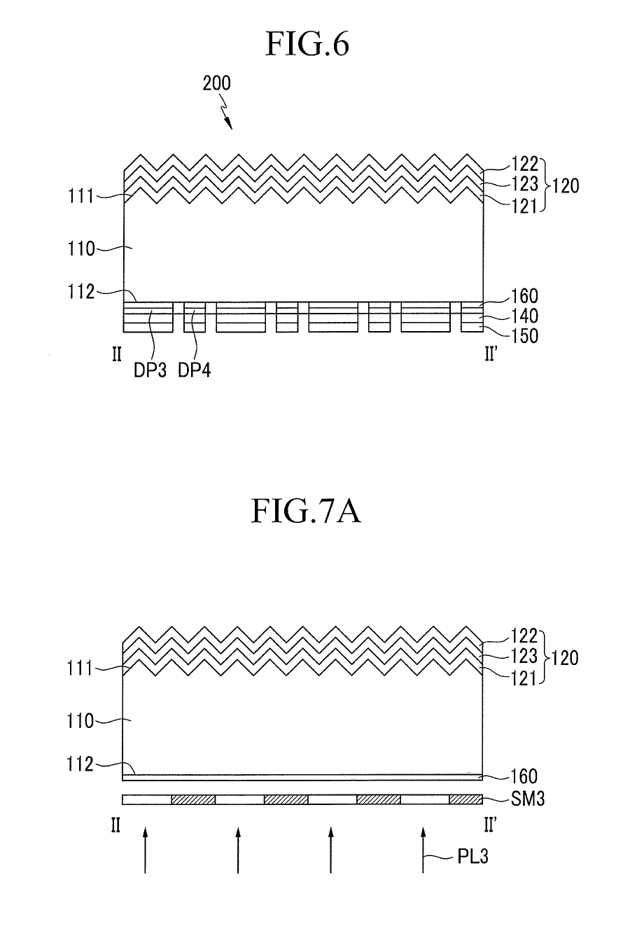

FIG. 5 is a perspective view illustrating a solar cell according to still another example embodiment of the present invention. FIG. 6 is a cross-sectional view taken along a line II-II′ of FIG. 5.

The solar cell according to the present example embodiment of FIG. 5 is substantially the same as the solar cell according to the previous example embodiment of FIG. 1 except for a method of forming first and second doped patterns. Thus, the same reference numerals will be used to refer to the same or like parts as those described in the previous example embodiment of FIG. 1 and any repetitive explanation concerning the above elements will be omitted.

Referring to FIG. 5 and FIG. 6, a solar cell 200 includes, for example, a substrate 110, a protection layer 120, a semiconductor layer 160, a first doped pattern DP3, a second doped pattern DP4, a contact layer 140 and an electrode layer 150.

The semiconductor layer 160 is formed on a rear surface 112 of the substrate 110. The semiconductor layer 160 includes, for example, i-type amorphous silicon. The semiconductor layer 160 may have, for example, a thickness between about 50 Å and about 100 Å.

The first doped pattern DP3 is formed on the semiconductor layer 160. The first doped pattern DP3 includes, for example, p-type silicon deposited with a first impurity gas. The first impurity gas may be, for example, boron trichloride (BCl₃) or diborane (B₂H₆). The second doped pattern DP4 is formed on the first semiconductor layer 160 and spaced apart from the first doped pattern DP3. The second doped pattern DP4 includes, for example, n-type silicon ((n+)-type silicon) deposited with a second impurity gas. The second impurity gas may be, for example, phosphine (PH₃). The first and second doped patterns DP3 and DP4 may have substantially the same shape as the first and second doped patterns DP1 and DP2 according to the previous example embodiment of FIG. 1, respectively.

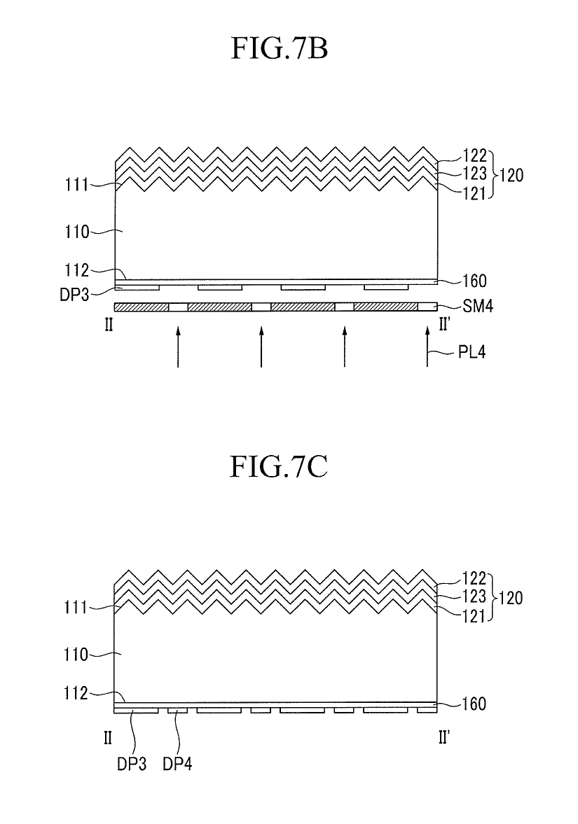

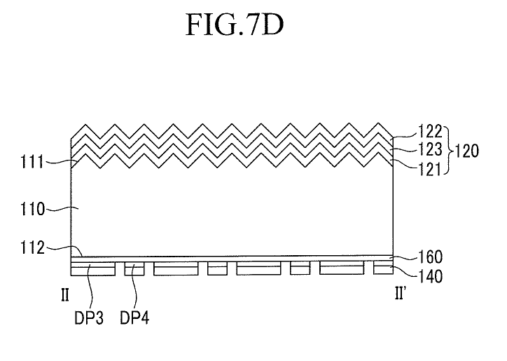

FIGS. 7A to 7D are cross-sectional views illustrating processes of manufacturing the solar cell of FIG. 5.

Referring to FIG. 7A, for example, a first doped pattern DP3 is formed on the semiconductor layer 160 including i-type amorphous silicon using a plasma enhanced chemical vapor deposition (PECVD) method. For example, a first shadow mask SM3 having an opening corresponding to the location in which the first doped pattern DP3 will be formed is disposed over the substrate 110 having the semiconductor layer 160. The substrate 110 is disposed in a chamber. In the chamber, a high energy due to a discharge of electricity and so on, is applied to generate first plasma PL3 from the first impurity gas. The first plasma PL3 includes atoms or ions generated from the first impurity gas, and the atoms or the ions are reacted with each other, so that a thin film is selectively deposited on the semiconductor layer 160. The first impurity gas may be, for example, a mixed gas having boron trichloride (BCl₃) or diborane (B₂H₆) added to silane (SiH₄) and hydrogen (H₂).

Referring to FIG. 7B and FIG. 7C, the second doped pattern DP4 is faulted on the semiconductor layer 160 having the first doped pattern DP3 using the PECVD method. For example, the second shadow mask SM4 having an opening corresponding to the location in which the second doped pattern DP4 will be formed is disposed over the substrate 110 having the first doping patter DP3. The substrate 110 is disposed in the chamber emitting the second impurity gas. In the chamber, the high energy due to the discharge of electricity and so on, is applied to the second impurity gas to generate second plasma PL4 from the second impurity gas. The second plasma PL4 includes atoms or ions generated from the second impurity gas, and the atoms or the ions are reacted with each other, so that a thin film is selectively deposited on the semiconductor 160 and spaced apart from the first doped pattern DP3. The second impurity gas may be, for example, a mixed gas having PH₃ added to SiH₄ and H₂. For example, the first doped pattern DP3 may have a thickness between about 50 Å and about 100 Å, and the second doped pattern DP4 may have about a thickness between about 50 Å and about 100 Å.

Referring to FIG. 7D, the contact layer 140 is formed on the first and second doped patterns DP3 and DP4 using, for example, a reactive plasma deposition (RPD) method, an ion plating deposition method or an inkjet printing method.

Referring to FIG. 6, the electrode layer 150 is formed on the contact layer 140 using, for example, a screen printing method.

According to the previous example embodiment of FIG. 5, the first and second doped patterns DP3 and DP4 are formed on the semiconductor layer 160 formed on the rear surface 112 of the substrate 110 using the plasma, so that a loss of the solar light incident into the front surface 111 of the substrate 110 may be decreased.

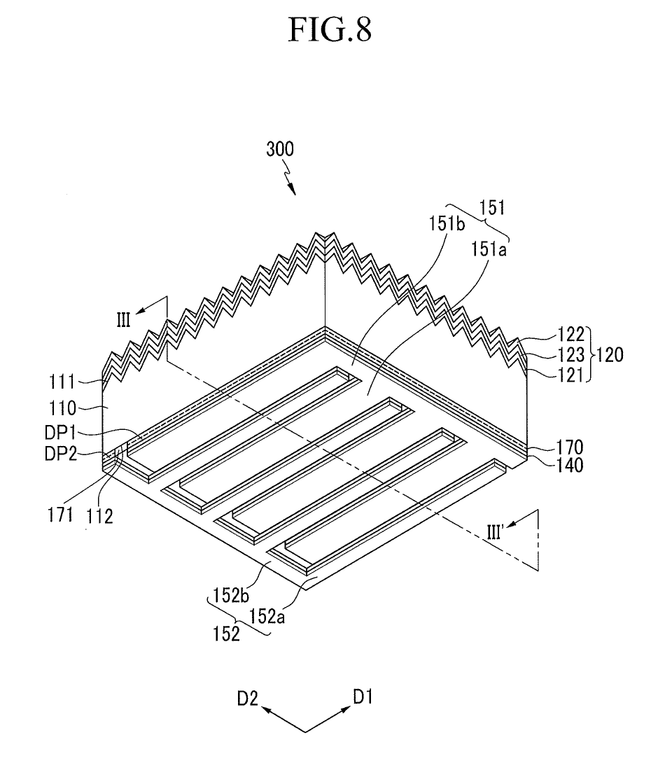

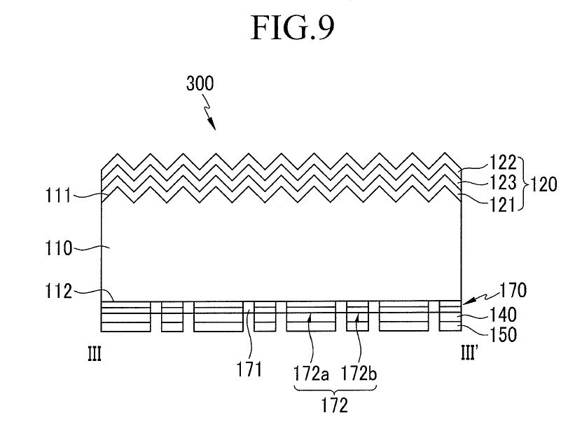

FIG. 8 is a perspective view illustrating a solar cell according to still another example embodiment of the present invention. FIG. 9 is a cross-sectional view taken along a line of III-III′ of FIG. 8.

The solar cell according to the present example embodiment of FIG. 8 is substantially the same as the solar cell according to the previous example embodiment of FIG. 1 except for a method of forming a semiconductor layer. Thus, the same reference numerals will be used to refer to the same or like parts as those described in the previous example embodiment of FIG. 1 and any repetitive explanation concerning the above elements will be omitted.

Referring to FIG. 8 and FIG. 9, a solar cell 300 includes, for example, a substrate 110, a protection layer 120, a semiconductor layer 170, a first doped pattern DP1, a second doped pattern DP2, a contacting layer 140 and an electrode layer 150.

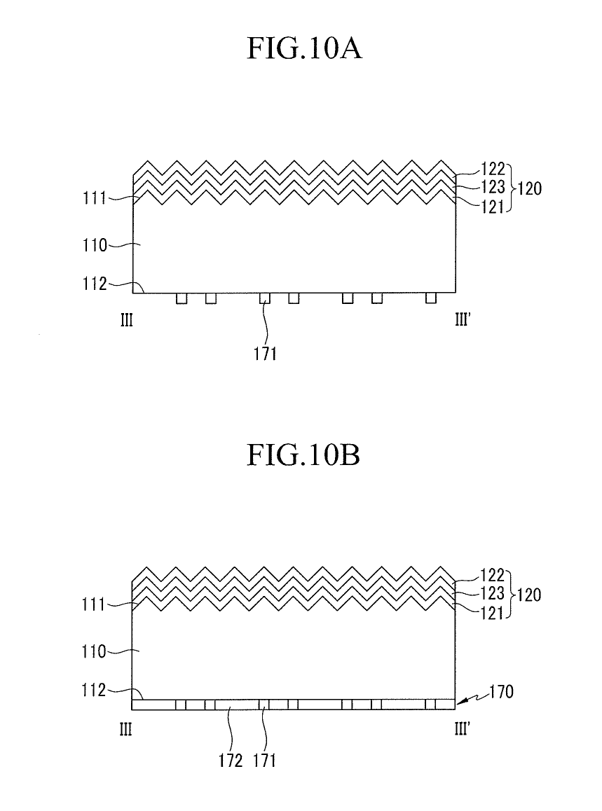

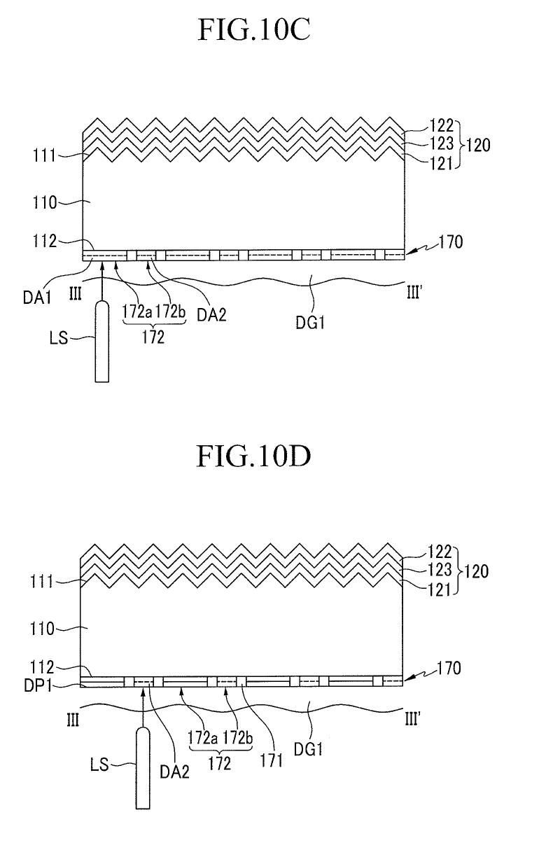

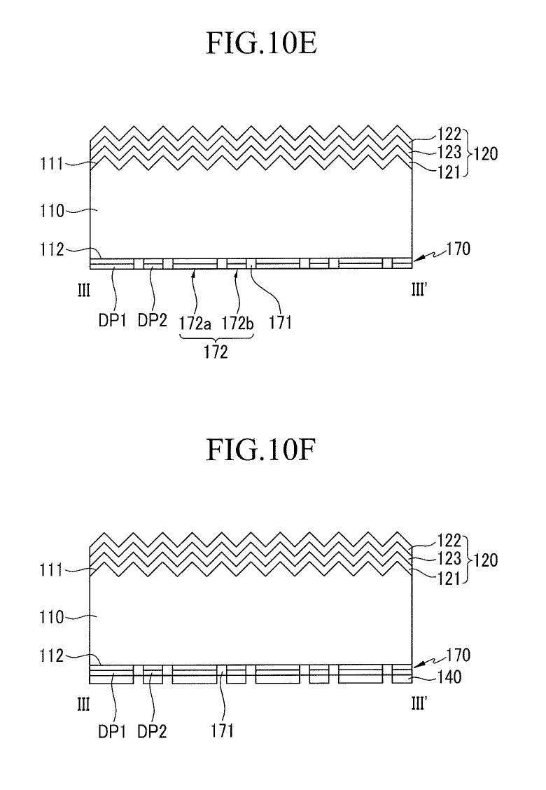

The semiconductor layer 170 is formed on the rear surface of the substrate 110. The semiconductor layer 170 includes, for example, an insulation pattern 171 and a semiconductor pattern 172. The insulation pattern 171 is formed on a first area of the rear surface 112 of the substrate 110. The semiconductor pattern 172 is formed on a second area of the rear surface 112 of the substrate 110 but not on the first area of the rear surface 112 of the substrate on which the insulation pattern 171 is formed. As will be illustrated and described in further detail with reference to FIGS. 10C, 10D and 10E, the semiconductor pattern 172 includes a first semiconductor pattern 172a and a second semiconductor pattern 172b spaced apart from each other. The insulation pattern 171 is disposed between the first and the second semiconductor patterns 172a, 172b.

The insulation pattern 171 includes, for example, silicon oxide (SiO₂). The semiconductor pattern 172 includes, for example, i-type amorphous silicon. Each of the insulation pattern 171 and the semiconductor pattern 172 may have, for example, a thickness between about 50 Å and about 100 Å.

The first semiconductor pattern 172a includes the first doped pattern DP1, and the second semiconductor pattern 172b includes the second doped pattern DP2. The first doped pattern DP1 includes, for example, p-type silicon doped with a first impurity gas. The first impurity gas DG1 may be, for example, boron trichloride (BCl₃) or diborane (B₂H₆). The second doped pattern DP2 includes n-type silicon (or (n+)-type silicon) doped with a second impurity gas DG2. The second impurity gas DG2 may be, for example, phosphine (PH₃).

The contact layer 140 is formed on the first and second semiconductor patterns 172a and 172b respectively including the first and second doped patterns DP1 and DP2, and the electrode layer 150 is formed on the contact layer 140.

FIGS. 10A to 10F are cross-sectional views illustrating processes of manufacturing the solar cell of FIG. 8.

Referring to FIG. 10A, the insulation pattern 171 is formed on the first area of the rear surface 112 using, for example, an inkjet printing method.

Referring to FIG. 10B, a shadow mask having an opening corresponding to the second area of the rear surface 112 except for the first area is disposed over the rear surface 112, and the semiconductor pattern 172 is formed on the substrate 110 using, for example, a plasma enhanced chemical vapor deposition (PECVD) method.

The semiconductor pattern 172 is divided into the first semiconductor pattern 172a and the second semiconductor pattern 172b by the insulation pattern 171 disposed between the first and the second semiconductor patterns 172a and 172b. The semiconductor layer 170 may have, for example, a thickness between about 100 Å and about 200 Å considering the thicknesses of the first and the second doped patterns DP1 and DP2 formed in the following process.

Thus, the semiconductor layer 170 including the insulation pattern 171 and the semiconductor pattern 172 is formed on the rear surface 112 of the substrate 110 after the protection layer 120 is formed on the front surface 111 of the substrate 110.

Referring to FIG. 10C, the first impurity gas DG1 is doped into a first doping area DA1 in the first semiconductor pattern 172a using, for example, a gas immersion laser doping (GILD) method. For example, the substrate 110 on which the semiconductor layer 170 is formed is disposed in a chamber emitting the first impurity gas DG1, and the first impurity gas DG1 adheres on a surface of the semiconductor layer 170. The first impurity gas DG1 may be, for example, boron trichloride (BCl₃) or diborane (B₂H₆).

Then, a laser LS as an energy source is injected onto the surface of the semiconductor layer 170 on which the first impurity gas DG1 adheres, and the first impurity gas DG1 is selectively doped into the first semiconductor pattern 172a. The first doped pattern DP1 may have, for example, the thickness between about 50 Å and about 100 Å.

After the first impurity gas DG1 is doped, the first impurity gas DG1 remaining on the surface of the semiconductor layer 170 may be removed by, for example, a dry rinsing.

Referring to FIG. 10D, the second impurity gas DG2 is doped into the second doping area DA2 spaced apart from the first doping area DA1 of the second semiconductor pattern 172b having the first doped pattern DP1 formed in the first doping area DA1 according to the above-mentioned process referring to FIG. 10C. For example, the substrate 110 having the first doped pattern DP1 is disposed in the chamber emitting the second impurity gas DG2, and the second impurity gas DG2 adheres on the surface of the semiconductor layer 170. The second impurity gas DG2 may be, for example, phosphine (PH₃).

Then, the laser LS as the energy source is injected onto the surface of the semiconductor layer 170 on which the second impurity gas DG2 adheres, and the second impurity gas DG2 is selectively doped into the second semiconductor pattern 172b spaced apart from the first semiconductor pattern 172A. The second doped pattern DP2 may have, for example, a thickness between about 50 Å and about 100 Å. The second doped pattern DP2 may have, for example, a width smaller than that of the first doped pattern DP1.

Referring to FIG. 10E, the second doped pattern DP2 is formed in the second doping area DA2 according to the above-mentioned process referring to FIG. 10D. The second doping patter DP2 may be insulated from the first doped pattern DP1 by the insulation pattern 171 formed between the first and the second semiconductor patterns 172a and 172b. After the second impurity gas DG2 is doped, the second impurity gas DG2 remaining on the surface of the semiconductor layer 170 may be removed by, for example, the dry rinsing.

Referring to FIG. 10F, the contact layer 140 is formed on the first and second doped patterns DP1 and DP2 of the semiconductor layer 170 using, for example, a reactive plasma deposition (RPD) method, an ion plating deposition method or an inkjet printing method.

Referring to FIG. 9 again, the electrode layer 150 is formed on the contact layer 140 using, for example, the screen printing method.

According to the present example embodiment of FIG. 8, the semiconductor layer 170 includes the insulation pattern 171, the first semiconductor pattern 172a and the second semiconductor pattern 172b, and the first and second doped patterns DP1 and DP2 of the solar cell 300 are respectively formed in the first and second semiconductor patterns 172a and 172b.

Alternatively, in the present example embodiment instead of using the gas immersion laser doping method to form the first and second doped patterns DP1 and DP2, the first and second doped patterns DP1 and DP2 may instead be formed using the plasma doping method according to the previous example embodiment of FIG. 4A and FIG. 4B, in which plasma is generated from an impurity gas, so that the first and second doped patterns DP1 and DP2 may be respectively formed in the first and second semiconductor patterns 172a and 172b.

Alternatively, in the present example embodiment instead of using the gas immersion laser doping method to form the first and second doped patterns DP1 and DP2, the first and second doped patterns DP1 and DP2 may instead be formed using the plasma enhanced chemical vapor deposition method according to the previous example embodiment of FIG. 5, in which plasma is generated from an impurity gas, so that the first and second doped patterns DP1 and DP2 may be respectively formed on the first and second semiconductor patterns 172a and 172b.

As with the previous example embodiment of FIGS. 1-3, the first and second doped patterns DP1 and DP2 of the solar cell 300 of the present example embodiment of FIGS. 8-10 are formed in the semiconductor layer 170 formed on the rear surface 112 of the substrate 110 using the first and second impurity gas and laser, so that a loss of the solar light incident into the front surface 111 of the substrate 110 may be decreased.

According to example embodiments of the invention, the first and second doped patterns are formed on a rear surface of a substrate of a solar cell, so that a loss of solar light received to a front surface of the substrate of the solar cell may be decreased.

In addition, in example embodiments of the present invention, the first and second doped patterns are formed in or on a semiconductor layer including an i-type amorphous semiconductor, so that the first doped pattern may be electrically insulated from the second doped pattern.

In addition, a first passivation film includes the i-type amorphous semiconductor, so that an absorption rate of the solar light may be increased.

Having described exemplary embodiments of the present invention, it is further noted that it is readily apparent to those of reasonable skill in the art that various modifications may be made without departing from the spirit and scope of the invention which defined by the metes and bounds of the appended claims.

What is claimed is:

1. A solar cell comprising:
a substrate having a first surface adapted to receive solar light and a second surface opposite to the first surface;
a semiconductor layer comprising an insulating pattern formed on a first area of the second surface of the substrate and a semiconductor pattern formed on a second area of the second surface of the substrate in which the insulating pattern is not formed; and
a first doped pattern and a second doped pattern formed either in or on the semiconductor pattern.

2. The solar cell of claim 1, wherein the semiconductor layer has a thickness between about 100 Å and about 200 Å,
the semiconductor pattern comprises a first semiconductor pattern and a second semiconductor pattern spaced apart from the first semiconductor pattern,
the first doped pattern is formed in the first semiconductor pattern, and the second doped pattern is formed in the second semiconductor pattern.

3. The solar cell of claim 1, wherein the semiconductor layer has a thickness between about 50 Å and about 100 Å,
the semiconductor pattern comprises a first semiconductor pattern and a second semiconductor pattern spaced apart from the first semiconductor pattern,
the first doped pattern is formed on the first semiconductor pattern, and the second doped pattern is formed on the second semiconductor pattern.

4. A method of manufacturing a solar cell, the method comprising:
forming a semiconductor layer on a second surface of a substrate opposite to a first surface of the substrate, the first surface adapted to receive solar light;
adhering a first impurity gas on the semiconductor layer; and
injecting a laser onto the semiconductor layer to form a first doped pattern in the semiconductor layer.

5. The method of claim 4, further comprising:
forming a contact layer on the first doped pattern using one of a reactive plasma deposition (RPD) method, an ion plating deposition method and an inkjet printing method.

6. The method of claim 5, further comprising:
forming an electrode electrically connected to the first doped pattern on the contact layer.

7. The method of claim 4, further comprising:
adhering a second impurity gas on the semiconductor layer having the first doped pattern; and
injecting the laser onto the semiconductor layer to form a second doped pattern in the semiconductor layer and spaced apart from the first doped pattern.

8. The method of claim 7, wherein the first doped pattern includes a plurality of first patterns extending in a first direction and a second pattern connecting the first patterns with each other,
the second doped pattern includes a plurality of third patterns extending in the first direction and formed adjacent to the first patterns, and a fourth pattern connecting the third patterns with each other, and
the first and the third patterns are alternately disposed.

9. The method of claim 7, wherein the semiconductor layer has a thickness between about 100 Å and about 200 Å.

10. The method of claim 7, wherein the first impurity gas includes one of boron trichloride (BCl₃) and diborane (B₂H₆), and the second impurity gas includes phosphine (PH₃).

11. The method of claim 4, wherein the semiconductor layer includes an insulation pattern and a semiconductor pattern,
wherein forming the semiconductor layer comprises:
forming the insulation pattern by an inkjet printing method on a first area of the second surface of the substrate; and
forming the semiconductor pattern on a second area of the second surface of the substrate in which the insulation pattern is not formed.

12. A method of manufacturing a solar cell, the method comprising:
forming a semiconductor layer on a second surface of a substrate opposite to a first surface of the substrate, the first surface adapted to receive solar light;
disposing a first mask having an opening portion over the semiconductor layer; and
providing a first plasma to the semiconductor layer through the first mask to form a first doped pattern in or on the semiconductor layer.

13. The method of claim 12, further comprising:
forming a contact layer on the first doped pattern using one of a reactive plasma deposition (RPD) method, an ion plating deposition method and an inkjet printing method.

14. The method of claim 13, further comprising:
forming an electrode electrically connected to the first doped pattern on the contact layer.

15. The method of claim 12, further comprising:
disposing a second mask having an opening portion over the semiconductor layer having the first doped pattern; and
providing a second plasma to the semiconductor layer through the second mask to form a second doped pattern in or on the semiconductor layer and spaced apart from the first doped pattern.

16. The method of claim 15, wherein the semiconductor layer has a thickness between about 100 Å and about 200 Å, and
the first and the second doped patterns are formed in the semiconductor layer.

17. The method of claim 16, wherein the first plasma is generated from one of boron trichloride (BCl₃) and diborane (B₂H₆), and the second plasma is generated from phosphine (PH₃).

18. The method of claim 15, wherein the semiconductor layer has a thickness between about 50 Å and about 100 Å, and
the first and the second doped patterns are deposited on the semiconductor layer.

19. The method of claim 18, wherein the first plasma is generated from one of boron trichloride (BCl₃) and diborane (B₂H₆), silane (SiH₄) and hydrogen (H₂), and the second plasma is generated from one of phosphine (PH₃), silane (SiH₄) and hydrogen (H₂).

20. The method of claim 12, wherein the semiconductor layer includes an insulation pattern and a semiconductor pattern,
wherein forming the semiconductor layer comprises,
forming the insulation pattern by an inkjet printing method on a first area of the second surface of the substrate; and
forming the semiconductor pattern on a second area of the second surface of the substrate in which the insulating pattern is not formed.

21. The method of claim 20, wherein the semiconductor layer has a thickness between about 100 Å and about 200 Å, and
the first doped pattern is formed in the semiconductor pattern.

22. The method of claim 20, wherein the semiconductor layer has a thickness between about 50 Å and about 100 Å, and the first doped pattern is deposited on the semiconductor pattern.
